(19) United States
(12) Patent Application Publication
(10) Pub. No.: US 2003/0063437 A1
(43) Pub. Date: Apr. 3, 2003

(54) Information processing unit and method for cooling same

(75) Inventor: Kazuo Kurihara, Ohta-shi (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/255,698

(22) Filed: Sep. 27, 2002

(30) Foreign Application Priority Data
Sep. 28, 2001 (JP) 2001-304241

(51) Int. Cl. H05K 7/20

(52) U.S. Cl. 361/688

(57) ABSTRACT

An information processing unit is provided in which, in a suspension mode, a chip temperature does not exceed a temperature specification, thus enabling unnecessary noise caused by a fan to be avoided and, even if semiconductor chips of different types are used, a common use of a motherboard can be achieved. When a suspension signal output from a power supply controlling section to control a supply power to be fed to a CPU is changed to a low level, a fan controlling section outputs a fan controlling signal adapted to lower a fan revolution speed to the fan.

### BACKGROUND OF THE INVENTION

1. Field of the Invention

The present invention relates to an information processing unit and a method for cooling the same and more particularly to the information processing unit configured so as to provide cooling for a semiconductor chip liberating large amounts of heat and the method for cooling the above information processing unit.

The present application claims priority of Japanese Patent Application No. 2001-304241 filed on Sep. 28, 2001, which is hereby incorporated by reference.

2. Description of the Related Art

A Personal Computer known as a representative example of an information processing unit is constructed by using a semiconductor chip such as a CPU (Central Processing Unit), semiconductor memory, or a like, as main components, however, heat is liberated, during operations of the personal computer, from many components including such the semiconductor chip. In particular, in the CPU serving as a central component to perform a function of an arithmetic operation in the personal computer, since its function is dramatically improved in response to a demand for a high processing capability required in recently available personal computers, amounts of arithmetic operations per unit time are increasing. As a result, an amount of heat liberated from the semiconductor chip making up the CPU further increases greatly.

As an amount of heat liberated from such the semiconductor chip increases, since a temperature (that is, a chip temperature) rises, operations of the CPU become unstable as the temperature rises and are put into a suspension state and, in the extreme, in some cases, the semiconductor chip itself is thermally broken. To solve this problem, conventionally, by mounting a cooling device (cooling means) such as a heat sink, fan, or a like on the semiconductor chip in order to inhibit a rise in a chip temperature, special consideration is given so that operations of the CPU are stabilized.

FIG. 6 is a plan view schematically showing an example of a configuration with a CPU 52 making up a conventional personal computer being mounted in an information processing unit. In the personal computer (not shown), as shown in FIG. 6, a CPU 52 made up of semiconductor chips is mounted at a desired place in a motherboard (wiring substrate) 51 on which many components (not shown) are packaged and, on the CPU 52, a fan 53, together with a heat sink (not shown), is mounted as a cooling means for cooling the CPU 53. Moreover, beside or on the CPU 52 is mounted a temperature sensor (not shown) to detect a temperature of a semiconductor chip. By configuring as above, since, by having the fan 53 rotate during operations of the personal computer to forcedly blow air on the CPU 52, the CPU 52 can be cooled and, therefore, it becomes possible to inhibit a rise in a chip temperature of the CPU 52 thus to successfully stabilize operations of the CPU 52.

Moreover, the personal computer is provided with a mode for a power saving function called a “suspension mode” which can be operated at a same time when a mode is being ordinarily used, in which, when an input device (input unit) such as a keyboard, mouse, or a like is not operated for a specified period of time, in order to achieve reduction in power consumption, a supply of a signal to peripheral devices such as a display, hard disk, or a like is temporarily stopped and operations of the CPU 52 are suspended and only minimal amounts of power required for starting smooth operations when the personal computer is re-started are supplied to the CPU 52. In such the suspension mode, since almost no semiconductor chips making up the CPU 52 liberate heat, the fan is kept in a suspension state.

As described above, there are some types of recently-available CPUs having achieved high performance in which power has to be supplied at all time though its power level is lower when compared with a level of power being applied at time of ordinary operations in order to have a specified function kept even in a suspension mode. In personal computers using such the CPU, since a semiconductor chip entails liberation of heat, as a natural result, in a suspension mode though an amount of the liberated heat is small when compared with an amount of liberated heat at a time of ordinary operations, the semiconductor chip has to be cooled by operations of a fan.

FIG. 7 is a timing chart explaining a method for cooling the semiconductor chip making up the CPU employed in the conventional personal computer (referred to as a “first conventional example”) by using a fan 53. As shown in FIG. 7, operation modes (time) are plotted as abscissa and a temperature A and a fan revolution speed B are plotted as ordinate. It is presumed that, at a time t0, a driven personal computer is performing its ordinary operation (S0) and a temperature of a semiconductor chip making up the CPU is set at “T” and a revolution speed of the fan 53 is set to be high. In this state, at subsequent time t1, when the operation mode of the personal computer is switched to a suspension mode (S1), a power saving function works and, as a result, the chip temperature T is lowered gradually. However, the fan 53 is kept at a high revolution speed as has been originally set.

Next, at a time t2, when the personal computer returns to its ordinary operation (S0), the CPU 52 causes the chip temperature T again to rise. At this point, the fan 53 is still kept at a high revolution speed as has been originally set. Next, by continuing the ordinary operation (S0), the chip temperature T still rises and, at a time t3, the chip temperature T exceeds a temperature threshold value Tt set in advance and the fan 53 is kept at the high revolution speed. Next, at a time t4, when the mode of the personal computer is switched again to the suspension mode (S1), its power saving function works, thereby causing the chip temperature T to be gradually lowered, however, the fan 53 is kept at the high revolution speed.

On the other hand, another conventional personal computer is proposed in which, when an operation mode of the personal computer is switched from an ordinary mode to a suspension mode (S1), a revolution speed of the fan 53 is switched from an intermediate speed to a stop state (referred to as a “second conventional example”). A method for providing cooling for the CPU 52 employed in the second conventional example is explained by referring to a timing chart shown in FIG. 8. As in the case shown in FIG. 7, it is presumed that, at a time the t0, a driven personal computer is performing its ordinary operation (S0) and a temperature of a semiconductor chip is set at “T” and a revolution speed of the fan is set to be intermediate. In this state, at subsequent time t1, when a mode of the personal computer is switched to a suspension mode (S1), a signal showing that the mode of the personal computer has been switched to the suspension mode (S1) by a temperature sensor (not shown) is output to a control section (not shown) by which a judgement is made in which cooling by the fan 53 is not required and by which the control section exerts control so that a revolution speed of the fan 53 is switched from an intermediate speed to a stop state. As a result, a chip temperature T gradually rises.

Next, at a time t2, when operation returns to the ordinary operation (S0), a detection that the CPU 52 has started its operations is made and the control section exerts control so that a revolution speed of the fan 53 is switched from its stop state to its intermediate state. As a result, a rise in the chip temperature T is inhibited. Next, if the chip temperature T further rises by continuing the ordinary operation (S0) and, at a time t3, the chip temperature T exceeds a temperature threshold value Tt which is preliminarily set, the control section detects this state and switches the fan revolution speed from its intermediate speed to its high speed.

Next, at a time t4, when the mode of the personal computer is switched to its suspension mode (S1), a judgement is made that cooling by the fan 53 is not required and the control section exerts control so that a revolution speed of the fan 53 is switched from its intermediate speed to its stop state. As a result, the chip temperature T rises gradually and exceeds a temperature set in advance in accordance with a temperature specification Td.

In the conventional information processing unit, since a semiconductor chip which requires a supply of power even in a suspension mode is used, cooling on the semiconductor chip liberating heat even in the suspension mode (S1) is needed. Therefore, following problems arise.

That is, in the conventional first example shown in FIG. 7, at a time t1 or t4, even after the personal computer has been switched from its ordinary operation (S0) to a suspension mode (S1), since the fan 53 is kept at a high revolution speed that has been originally set, unnecessary noises caused by the fan 53 occur. That is, in the suspension mode, since the fan 53 is not operated at a most suitable revolution speed to respond to heat liberation of the semiconductor chip, it is impossible to avoid occurrence of unnecessary noises caused by the fan 53. As a result, since a user hears a large noise even in a suspension mode, he/she has a feeling of anxiety or confusion as to whether or not the personal computer is normally operating.

Next, in the second conventional example shown in FIG. 8, at a time t1 and t4, when the personal computer is switched from its ordinary operation (S0) to a suspension mode (S1), since an operation of the fan 53 is stopped, unlike in the case of the first conventional example, the occurrence of unnecessary noises caused by the fan 53 can be avoided.

However, in the second conventional example, when the personal computer is switched from its ordinary operation (S0) to the suspension mode (S1), since a revolution speed of the fan 53 has been switched from its high speed to a stop state, cooling by the fan 53 is not performed and therefore the chip temperature T exceeds the temperature specification Td. As a result, it is made difficult to stabilize operations of the CPU 52.

To avoid such the occurrence of unnecessary noises caused by the fan 53, technology can be used which exerts control on the fan 53 revolution speed according to a rise and a fall in the chip temperature T by monitoring the chip temperature T using software. However, in this case, since a memory, arithmetic calculation circuit, control circuit, power source, or a like are required, the technology does not serve a purpose of the suspension mode, that is, a purpose of a power savings. Moreover, an increase in an amount of liberated heat caused by an operation of the software occurs.

Moreover, limitations of heat resistance in the CPU 52 being employed in the personal computer differ depending on a characteristic of each kind of CPUs. That is, since the characteristic of each CPU 52 is different from each other, timing with which a revolution speed of the fan 53 is switched (to a high, intermediate, or low speed) and the temperature threshold value Tt differ in every type of the CPU 52. In this regard, conventionally, since the temperature threshold value Tt of the CPU 52 to be attached is designed in every motherboard 51, it is not possible to obtain a common standard of the motherboard 51 for the CPU 52 of a different kind. For example, if the CPU 52 having a high heat-resistance is mounted on the motherboard 51 designed so that the CPU 52 having a low temperature threshold value is to be placed, since the fan 53 starts operation at a time of a low chip temperature, noises from the fan 53 occur at an early stage.

In this case, the CPU 52 having a high heat-resistance has to be mounted on a motherboard 51 designed so that the CPU 52 having a high temperature threshold value is to be placed. As a result, a plurality of types of the motherboards 51 depending on a type of the CPU 52 has to be prepared, thus causing an increase in costs.

### SUMMARY OF THE INVENTION

In view of the above, it is an object of the present invention to provide an information processing unit which is capable of preventing a chip temperature from exceeding a temperature set in accordance with a specification and of avoiding occurrence of unnecessary noises caused by a fan and of achieving shared use of a motherboard even when semiconductor chips of various kinds are used and a method for cooling the information processing unit.

According to a first aspect of the present invention, there is provided an information processing unit having at least one semiconductor chip liberating a large amount of heat and being configured so as to cool the semiconductor chip using a cooling unit, including:

a power source controlling section to output, when a change in supply power to be fed to the semiconductor chip occurs, a supply power changing signal;

a cooling unit controlling section to output a cooling unit controlling signal in response to the supply power changing signal; and

wherein, when the supply power changing signal is input from the power source controlling section to the cooling unit controlling section at a time of driving, the cooling unit controlling section is configured so as to calibrate cooling capability of the cooling unit.

According to a second aspect of the present invention, there is provided an information processing unit having at least one semiconductor chip liberating a large amount of heat and being configured so as to cool the semiconductor chip using a cooling unit including:

a power source controlling section to output, when a change in supply power to be fed to the semiconductor chip occurs, a supply power change signal;

a fan controlling section to output a fan controlling signal according to the supply power change signal; and

wherein the supply power change signal is input from the power source controlling section to the fan controlling section at a time of driving, the fan controlling section is configured so as to lower a fan revolution speed.

In the foregoing, a preferable mode is one that wherein includes a temperature monitoring section in which a plurality of temperature threshold values corresponding to a characteristic of each of semiconductor chips of two and more types is stored in advance, and which is selectively set to a temperature threshold value corresponding to the embedded semiconductor chip, when arbitrary one semiconductor chip out of semiconductor chips of two or more types is embedded.

According to a third aspect of the present invention, there is provided an information processing unit having at least one semiconductor chip liberating a large amount of heat and being configured so as to cool the semiconductor chip using a fan including:

a temperature monitoring section in which a plurality of temperature threshold value corresponding to a characteristic of each of semiconductor chips of two and more types is stored in advance, and which the temperature threshold value is set selectively to a temperature threshold value corresponding to the embedded semiconductor chip, when arbitrary one semiconductor chip out of the semiconductor chips of two or more types is embedded, and which outputs an alarm signal when the temperature of the semiconductor chip exceeds the temperature threshold value;

a fan controlling section to output a fan controlling signal in response to an alarm signal; and

wherein, when the alarm signal is input from the temperature monitoring section to the fan controlling section at a time of driving, the fan controlling section is configured so as to increase a fan revolution speed.

According to a fourth aspect of the present invention, there is provided an information processing unit having at least one semiconductor chip liberating a large amount of heat and being configured so as to cool the semiconductor chip using a fan including:

a power source section to feed supply power to the information processing unit;

a fan controlling section to detect a change in fed amounts of the supply power and, based on a result from the detection, to output a fan controlling signal; and

wherein, when a signal showing a change in the fed amounts of the supply power is input from the power source section to the fan controlling section at a time of driving, the fan controlling section is configured so as to lower a fan revolution speed.

In the foregoing, a preferable mode is one wherein the semiconductor chip is made up of a CPU (Central Processing unit Unit).

Also, a preferable mode is one wherein the power source controlling section outputs one signal making up a binary signal as the signal showing a change in the amount of the supply power while the information processing unit performs an ordinary operation and outputs another signal making up the binary signal when the information processing unit is switched from its ordinary operation mode to its power saving mode.

Also, a preferable mode is one wherein the temperature monitoring section includes a BIOS (Basic Input/Output System) which stores in advance, a relative table showing a relation between the semiconductor chip and the temperature threshold value for every semiconductor chip of a different type.

Also, a preferable mode is one wherein, when one signal making up the binary signal is output as the signal showing a change in the amount of the supply power from the power source controlling section, the fan controlling section outputs a fan controlling signal to lower a fan revolution speed.

Also, a preferable mode is one wherein, wherein the semiconductor chip is mounted in a socket on a common motherboard in a manner so as to be attachable and detachable.

According to a fifth aspect of the present invention, there is provided a method for cooling an information processing unit having at least one semiconductor chip liberating a large amount of heat including:

a step of outputting a supply power changing signal from a power source controlling section to a cooling unit controlling section when supply power to be fed to the semiconductor chip is changed;

a step of calibrating cooling capability of a cooling unit by using the cooling unit controlling section when the supply power changing signal is input from the power source controlling section to the cooling unit controlling section at a time of driving.

According to a sixth aspect of the present invention, there is provided a method for cooling an information processing unit having at least one semiconductor chip liberating a large amount of heat including:

a step of outputting a supply power changing signal from a power source controlling section to a fan controlling section when supply power to be fed to the semiconductor chip is changed; and

a step of lowering a fan revolution speed using the fan controlling section when the supply power changing signal is input from the power source controlling section to the fan controlling section at a time of driving.

According to a seventh aspect of the present invention, there is provided a method for cooling an information processing unit having at least one semiconductor chip liberating a large amount of heat including:

a step of storing in advance a plurality of temperature threshold values corresponding to a characteristic of each of semiconductor chips of two or more types and, when arbitrary one semiconductor chip out of semiconductor chips of two or more types is embedded, of setting selectively the temperature threshold value to a temperature threshold value corresponding to the embedded semiconductor chip;

a step of outputting an alarm signal from a temperature monitoring section to a fan controlling section when a temperature of the semiconductor chip exceeds the temperature threshold value; and

a step of increasing a fan revolution speed using the fan controlling section when the alarm signal is input from the temperature monitoring section to the fan controlling section at a time of driving.

According to a eighth aspect of the present invention, there is provided a method for cooling an information processing unit having at least one semiconductor chip liberating a large amount of heat including:

a step of outputting a signal showing a change in amounts of supply power from a power source section to feed supply power to the information processing unit to a fan controlling section; and

a step of lowering a fan revolution speed using the fan controlling section when the signal showing a change in the amount of the supply power is input from the power source section to the fan controlling section at a time of driving.

With the above configuration, when a change occurs in a supply power to be fed to a semiconductor liberating a large amount of heat, since the fan controlling section outputs a fan controlling signal adapted to lower a fan revolution speed, even if a mode of the information processing unit is switched to the suspension mode, occurrence of noise caused by the fan can be inhibited.

Moreover, when an information processing unit is switched from its normal operation mode to its suspension mode, since a fan revolution speed is not switched from its high speed state to a stopped state, cooling using the fan can be achieved.

Furthermore, since at least one semiconductor chip liberating a large amount of heat is constructed so as to be attachable and detachable to a socket mounted on a motherboard, semiconductor chips of different types can be attached to a common motherboard. Therefore, in the suspension mode, a chip temperature does not exceed a temperature specification, which enables unnecessary noise caused by the fan to be avoided and even if semiconductor chips of different types are used, a common use of the motherboard can be achieved.

### BRIEF DESCRIPTION OF THE DRAWINGS

The above and other objects, advantages, and features of the present invention will be more apparent from the following description taken in conjunction with the accompanying drawings in which:

FIG. 1 is a schematic block diagram showing configurations of an information processing unit according to a first embodiment of the present invention;

FIG. 2 is a diagram for showing a suspension signal output from a power source controlling section in the information processing unit according to the first embodiment of the present invention;

FIG. 3 is a diagram for showing a temperature threshold value set, depending on a type of a CPU, to a temperature monitoring section of the information processing unit according to the first embodiment of the present invention;

FIG. 4 is a diagram for showing a fan controlling signal output from a fan controlling section in the information processing unit according to the first embodiment of the present invention;

FIG. 5 is a timing chart for explaining a method for cooling a CPU in the information processing unit by using a fan according to the first embodiment of the present invention;

FIG. 6 is a plan view schematically showing a configuration with a CPU making up a conventional personal computer being mounted in an information processing unit;

FIG. 7 is a timing chart explaining a method for providing cooling for the CPU employed in the conventional information processing unit (first conventional example) using a fan; and

FIG. 8 is a timing chart for explaining an other method for providing cooling for the CPU employed in the conventional information processing unit (second conventional example) using the fan.

### DETAILED DESCRIPTION OF THE PREFERRED EMBODIMENTS

Best modes of carrying out the present invention will be described in further detail using various embodiments with reference to the accompanying drawings.

### First Embodiment

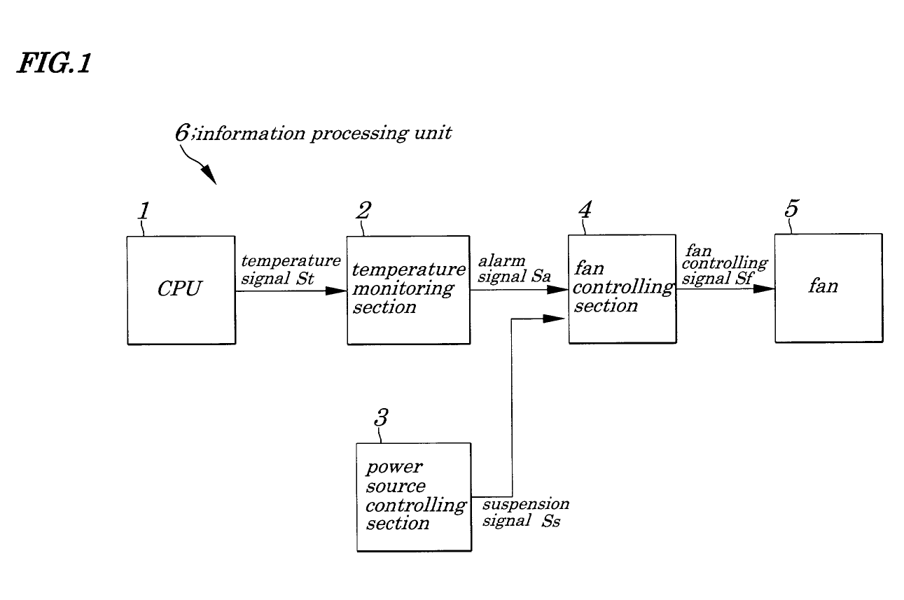

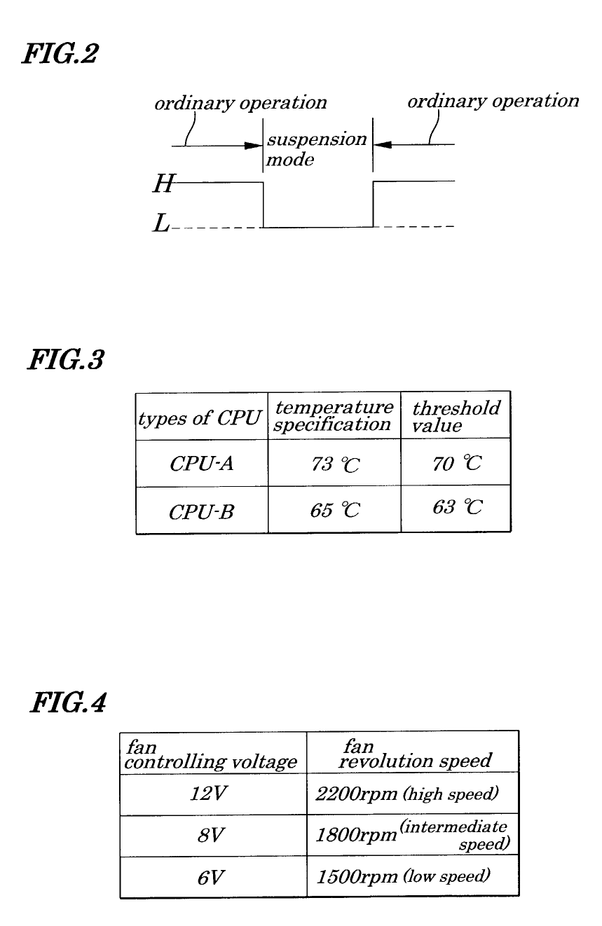

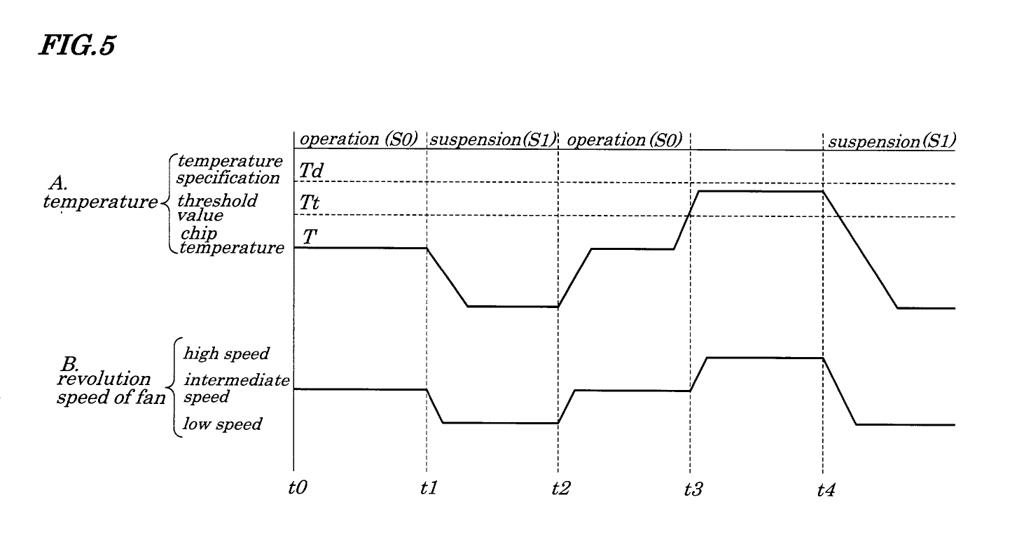

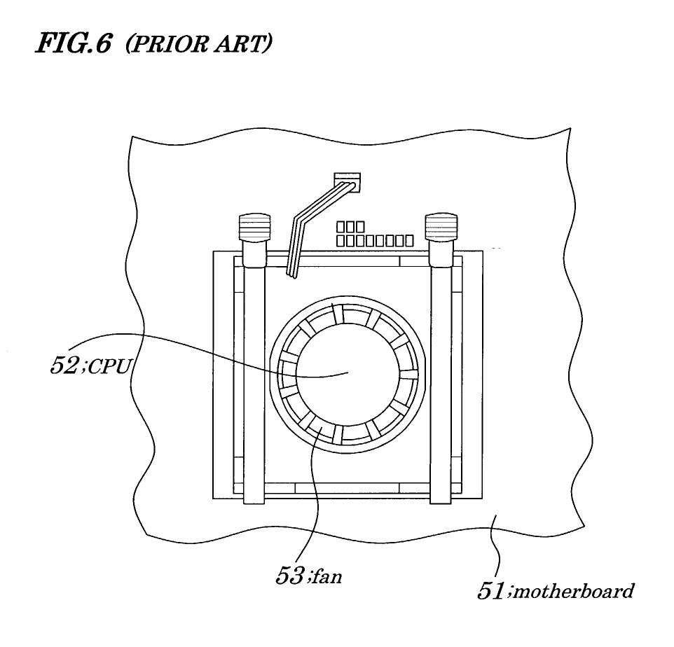

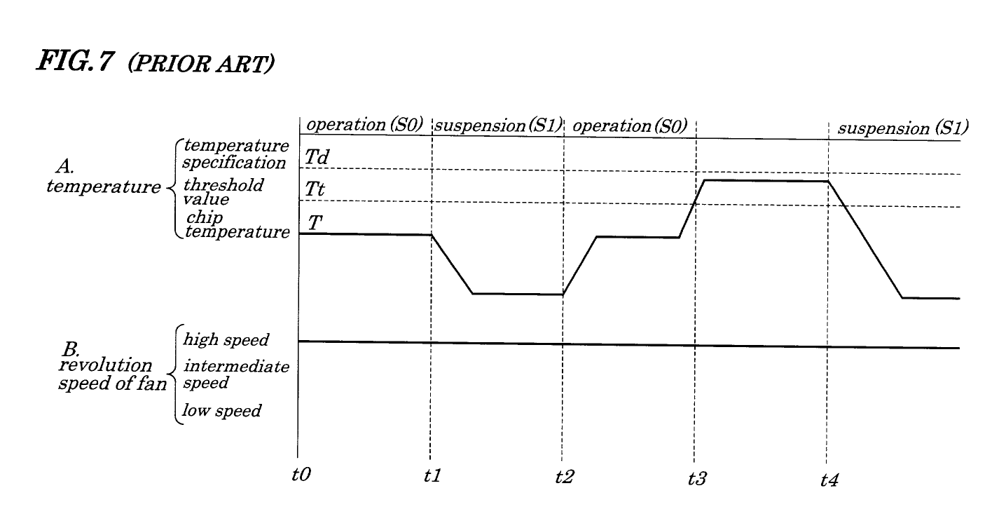

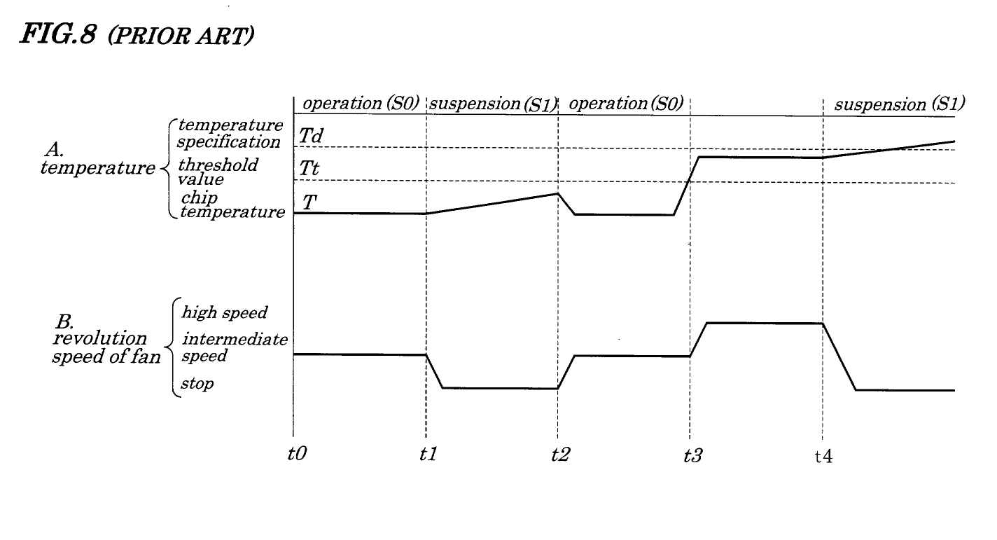

FIG. 1 is a schematic block diagram showing configurations of an information processing unit according to a first embodiment of the present invention. FIG. 2 is a diagram showing a suspension signal output from a power source controlling section in the information processing unit according to the first embodiment. FIG. 3 is a diagram showing a temperature threshold value set, depending on a type of a CPU, to a temperature monitoring section of the information processing unit according to the first embodiment. FIG. 4 is a fan controlling voltage from a fan controlling section 4 in the information processing unit according to the first embodiment. FIG. 5 is a timing chart explaining a method for cooling a CPU in the information processing unit according to the first embodiment. Moreover, in the embodiment, the information processing unit is applied to a personal computer.

An information processing unit (personal computer) 6, as shown in FIG. 1, includes a CPU 1 made up of semiconductor chips serving as a central component having an arithmetic operating function for the personal computer, a temperature monitoring section 2 into which a temperature signal St indicating a chip temperature detected by a temperature sensor (not shown) mounted on the CPU 1 is input and from which an alarm signal Sa is output depending on the temperature signal St when an embedded semiconductor chip exceeds a temperature threshold value, a power source controlling section 3 which controls supply power to be fed to the CPU 1 and outputs a suspension signal (supply power changing signal) Ss, the fan controlling section 4 which outputs a fan controlling signal Sf depending on an output signal fed from the temperature monitoring section 2 or a suspension signal Ss fed from the power source controlling section 3, and a fan 5 a revolution speed of which is controlled by the fan controlling signal Sf.

Moreover, the temperature monitoring section 2 stores, in advance, a plurality of temperature threshold values corresponding to a characteristic of each of the semiconductor chips of two or more types and, when one arbitrary semiconductor chip out of the semiconductor chips of the two or more types is embedded, sets selectively the temperature threshold value to a temperature threshold value corresponding to the embedded semiconductor chip and outputs the alarm signal Sa when a temperature of the semiconductor chip exceeds its temperature threshold value.

The suspension signal Ss output from the power source controlling section 3, as shown in FIG. 2, is output, while the personal computer is performing an ordinary operation, an H (high) level signal and is also output, when the personal computer switches its operation mode from its ordinary operation to its suspension mode, an L (low) level signal. Therefore, by confirming a level of the suspension signal Ss using the fan controlling section 4, whether or not the personal computer is performing its ordinary operation or whether or not the personal computer switches its mode from its ordinary operation to its suspension mode can be checked.

In the temperature monitoring section 2, as shown in FIG. 3, a plurality of temperature threshold values corresponding to a characteristic of each of the semiconductor chips of various types, for example, temperature threshold values for every CPU operating in accordance with a different temperature specification (that is, a characteristic), is stored in advance. For example, in the case of a CPU-A operating in accordance with a temperature specification being as relatively high as 73° C., a temperature specification being as relatively high as 70° C. is set as a temperature threshold value. On the other hand, for example, in the case of a CPU-B operating in accordance with a temperature specification being relatively low as 65° C., a temperature specification being as relatively low as 63° C. is set as a temperature threshold value. Specifically, a relative table showing a relation between the semiconductor chip and the temperature threshold value for every semiconductor chip having a different type is stored in a BIOS (Basic Input Output System). This enables an adjustment of timing with which a fan revolution speed (high, intermediate, or low speed) can be switched depending on a temperature specification of a CPU being used in the personal computer, that is, on a limitation of heat resistance. The CPU 1 is so configured as to be detachable and attachable from and to a socket mounted on a motherboard of the personal computer. This allows even a CPU of a different type to be attachable to a common motherboard. As a result, preparation of motherboards of a plurality of kinds depending on a kind of the CPU is not necessary.

The fan controlling signal Sf output from the fan controlling section 4, as shown in FIG. 4, is so configured to make a fan controlling voltage being different depending on a chip temperature of a detected CPU 1 be output to the fan 5 and a fan revolution speed to be changed at a time of operations of the fan 5 so that cooling capability is calibrated at every occasion. For example, when a chip temperature being relatively low is detected, control is exerted so that a fan controlling voltage being as relatively low as 6V is output as the fan controlling signal Sf to the fan 5 and a revolution speed of the fan 5 is changed to be 1500 rpm (low speed) so as to lower a cooling capability of the fan 5. Moreover, when a chip temperature being relatively high is detected, control is exerted so that a fan controlling voltage being as relatively high as 12V is output as the fan controlling signal Sf to the fan 5 and a revolution speed of the fan 5 is changed to be 2200 rpm (high speed) so as to increase cooling capability of the fan 5. Furthermore, when a chip temperature being relatively intermediate is detected, control is exerted so that a fan controlling voltage being as relatively intermediate as 8V is output as the fan controlling signal Sf to the fan 5 and a revolution speed of the fan 5 is changed to be 1800 rpm (intermediate speed) so as to calibrate a cooling capability of the fan 5 to be operated at an intermediate level.

Next, a method for cooling a semiconductor chip making up a CPU 1 in the personal computer using the fan 5 will be described by referring to FIG. 5. Here, one example using a CPU-A shown in FIG. 3 as the CPU 1 shown in FIG. 1 is described. In FIG. 5, an operation mode (time) is plotted as abscissa and a temperature A and a fan revolution speed B as ordinate. A temperature threshold value Tt being 70° C. corresponding to 73° C. being a temperature specification in the CPU-A shown in FIG. 3 is set in advance in the temperature monitoring section 2. In FIG. 5, at a time t0, when the personal computer is performing an ordinary operation (S0), a chip temperature T of a semiconductor chip (in the example, CPU-A) making up the CPU 1 is set to be lower than a temperature specification 73° C. and the fan controlling section 4 outputs a fan controlling voltage being 8V to the fan 5 as the fan controlling signal Sf and a revolution speed of a fan is set to be at an intermediate speed of 1800 rpm. The revolution speed of the fan 5 is made changeable, if necessary, depending on a performance of the CPU 1. In this state, the suspension signal Ss output from the power controlling section 3 is at the H (high) level in FIG. 2.

Next, at a time t1, when the personal computer is switched to a suspension mode (S1), a power saving function works and the chip temperature T gradually is lowered and the suspension signal Ss output from the power controlling section 3 is changed to be at the L (low) level. The fan controlling section 4, based on the L level signal, outputs a fan controlling voltage being 6V to the fan 5 as the fan controlling signal Sf and the revolution speed of the fan 5 is set to be at the low speed of 1500 rpm. As a result, cooling capability using the fan 5 is lowered.

Thus, according to the example, by confirming the suspension signal Ss output from the power controlling section 3 using the fan controlling section 4, at the time t1, when a level of its output is changed to be at the L (low) level, since the fan controlling section 4 outputs the fan controlling signal Sf used to lower a fan revolution speed to the fan 5, when the personal computer is switched to a suspension mode, it is possible to avoid unnecessary noise caused by the fan 5.

Next, at a time t2, when the personal computer is returned to an ordinary operation (S0), the operation of the CPU 1 causes the chip temperature T to rise again. A suspension signal Ss output from the power source controlling section 3 is changed to be at the H (high) level, since the temperature signal St showing a rise in the temperature is output from the temperature sensor (not shown) mounted in the CPU 1 to the temperature monitoring section 2, the temperature monitoring section 2 outputs an alarm signal Sa depending on the temperature signal St. In response to this signal, the fan controlling section 4 outputs a fan controlling voltage of 8V to the fan 5 as the fan controlling signal Sf and a revolution speed of the fan 5 is set to be at an intermediate speed of 1800 rmp. As a result, since cooling capability using the fan 5 increases, a rise in the chip temperature T of the CPU 1 is inhibited.

Next, personal computer's continuation of the ordinary operation (S0) causes the chip temperature T to further rise and, at a time t3, when the chip temperature T exceeds a temperature threshold value 70° C. set in advance, since a temperature signal St showing a rise in the chip temperature T is output to the temperature monitoring section 2 from a temperature sensor mounted in the CPU 1, the temperature monitoring section 2 outputs the alarm signal Sa in response to its temperature signal St. This indicates that a chip temperature T of the semiconductor chip comes near to a temperature specification Td. Based on this, the fan controlling section 4 outputs a fan controlling voltage of 12V as the fan controlling signal Sf and the revolution speed of the fan 5 is set to be at a high speed of 2200 rmp. As a result, since cooling capability further increases, a rise in the chip temperature T in the CPU 1 is inhibited.

Next, at a time t4, when the personal computer is switched to the suspension mode (S1), a power saving function works and the chip temperature T gradually is lowered and the suspension signal Ss output from the power source controlling section 3 is changed to be at the L (low) level. The fan controlling section 4, based on the L level signal, outputs a fan controlling voltage of 6V to the fan 5 as the fan controlling signal Sf and the revolution speed of the fan 5 is set to be at a low speed of 1500 rmp. As a result, cooling capability of the fan 5 is lowered.

Thus, according to the embodiment, by confirming the suspension signal Ss output from the power source controlling section 3 using the fan controlling section 4, at the time t4, when its output level is changed to be at the L level, since the fan controlling section 4 outputs the fan controlling signal Sf used to lower the fan revolution speed to the fan 5, when the personal computer is switched to a suspension mode (S1), occurrence of unnecessary noise caused by the fan 5 can be avoided. Therefore, there is neither anxiety nor confusion to users.

Next, when a CPU-B shown in FIG. 3 is used as the CPU 1 shown in FIG. 1, after the temperature threshold value Tt of 63° C. corresponding to the temperature specification of 65° C. has been stored in advance in the temperature controlling section 2, even when same cooling method as in the case of using the CPU-A, as the CPU 1, is used. In this case, in FIG. 5, at the time t1 and thereafter, personal computer's continuation of the ordinary operation (S0) causes the chip temperature T to further rise and, at the time t3, when the chip temperature T exceeds the temperature threshold value of 63° C. set in advance, a temperature signal St indicating a rise in a chip temperature T is output from the temperature sensor mounted in the CPU 1 to the temperature monitoring section 2, the temperature monitoring section 2 outputs the alarm signal Sa depending on the temperature signal St. Based on this, the fan controlling section 4 outputs the fan controlling voltage of 12V to the fan 5 as the fan controlling signal Sf and the revolution speed of the fan 5 is set to be at 2200 rmp. As a result, cooling capability by the fan 5 further increases, a rise in the chip temperature T of the CPU 1 is inhibited.

Except the above, almost the same operations as performed in a case in which the CPU-A is used are performed. Therefore, when a suspension signal Ss output from the power controlling section 3 is changed to be at the L level at the time t1 and t4, since a fan controlling signal Sf used to lower a revolution speed of the fan 5 is output by the fan controlling section 4, when the personal computer is changed to be a suspension mode (S1), unnecessary noise caused by the fan 5 can be avoided.

As described above, according to the information processing unit 6 of the embodiment, after the suspension signal Ss output from the power source controlling section 3 to control supply power fed to the CPU 1 is confirmed, when a change in the supply power occurs and its output is changed to be the L level, the fan controlling section 4 outputs a fan controlling signal Sf used to lower a fan revolution speed to the fan 5, when the personal computer is switched to the suspension mode (S1), unnecessary noise caused by the fan 5 can be avoided. Therefore, as in the case of the first conventional example, when the personal computer is switched from its ordinary operation (S0) to its suspension mode (S1), the fan revolution speed is kept at the high speed set originally, which stops occurrence of unnecessary noise caused by the fan 5.

Moreover, according to the information processing unit 6 of the embodiment, at the time t0 and Lime t4, when a change in the supply power occurs and a suspension signal Ss is changed to be at the L level, the fan controlling section 4 outputs the fan controlling signal Sf used to lower the fan revolution speed to the fan 5. However, as in the case of the second conventional example, at the time t1 and t4, when the personal computer is changed from its ordinary operation (S0) to its suspension mode (S1), since a fan revolution speed is not changed from a high speed to a stopped state to avoid unnecessary noise caused by the fan 5, cooling using the fan 5 is not performed thus there occurs no case in which a chip temperature T exceeds a temperature specification Td.

Moreover, according to the information processing unit 6 of the embodiment, the CPU 1 is constructed in a manner so as to be attachable and detachable to a socket mounted in a motherboard, any CPU being different in types can be attached to a common motherboard and therefore preparation for a plurality of motherboards depending on a type of the CPU 1 is not necessary. As a result, reduction in costs is made possible.

As described above, as shown in FIG. 3, by setting, in advance, a relative table for every CPU 1 being different in types, that is, being different in temperature specifications to the temperature monitoring section 2, effects described above can be obtained in the case of using any kind of the CPU 1.

Thus, according to the information processing unit 6 of the embodiment, when a suspension signal Ss output from the power source controlling section 3 adapted to control supply power to be fed to the CPU 1 is changed to be at the L level, since the fan controlling section 4 outputs the fan controlling signal Sf used to lower the revolution speed of the fan 5, when the personal computer is switched to a suspension mode (S1), noise caused by the fan 5 can be inhibited. Moreover, according to the information processing unit 6 of the embodiment, when the personal computer is switched from its ordinary operation (S0) to a suspension mode (S1), since the revolution speed of the fan 5 cannot be switched from a high speed state to a stopped state, cooling using the fan 5 can be performed.

Furthermore, according to the information processing unit 6 of the embodiment, the CPU 1 is constructed in a manner so as to be attachable and detachable to a socket mounted in a motherboard, any CPU being different in types can be attached to a common motherboard and therefore preparation for a plurality of motherboards depending on a type of the CPU is not necessary. Therefore, in the suspension mode (S1), the chip temperature T does not exceed a temperature specification and therefore unnecessary noise caused by the fan 5 can avoided and a common use of a motherboard using a semiconductor chip of a different type can be made possible.

It is apparent that the present invention is not limited to the above embodiments but may be changed and modified without departing from the scope and spirit of the invention. For example, the present invention is not limited to the fan 5 shown in the embodiment. That is, so long as a degree (cooling capability) of cooling the semiconductor chip can be calibrated, other cooling means such as water, gas, or a like can be used. Moreover, in the embodiment, an example is provided in which the fan controlling signal Sf is output, in response to the suspension signal Ss output from the power source controlling section 6, from the fan controlling section 4, however, the fan controlling signal Sf is not limited to such the suspension signal Ss. That is, a power source controlling section 3 to feed supply power to the information processing unit and the fan controlling section 4 used to detect a change in an amount of the supply power and to output the fan controlling signal Sf based on the change are provided. According to the example, a purpose can be achieved without outputting the suspension signal Ss being a special signal.

Moreover, in the embodiment, an example is provided in which an information processing unit is applied to the personal computer However, so long as a semiconductor chip liberating a large amount of heat at a time of operation such as a CPU is used, the present invention can be applied to an other information processing unit such as PDA (Personal Digital Assistants).

As a semiconductor chip liberating a large amount of heat, a semiconductor chip used in the CPU is employed in the embodiment, however, a chip set controlling a signal or other semiconductor chip being used for graphical drawing or a like can be applied. A signal that can be used is not limited to a suspension signal Ss output from the power source controlling section 3 so long as it is a signal showing a change in the supply power and other signals can be used. Moreover, the suspension signal Ss that can be used is not limited to that used in the embodiment. A signal in which its voltage is reversed between an H level and an L level, that is, a binary signal having its H and L levels may be employed as the suspension signal. Furthermore, in the embodiment, the value of temperature specification and temperature threshold value of a CPU, a fan control voltage, a fan revolution speed, or a like is provided as one example and therefore these values may be changed depending on a purpose, application or a like.

What is claimed is:

1. An information processing unit having at least one semiconductor chip liberating a large amount of heat and being configured so as to cool said semiconductor chip using a cooling unit, comprising:
a power source controlling section to output, when a change in supply power to be fed to said semiconductor chip occurs, a supply power changing signal;
a cooling unit controlling section to output a cooling unit controlling signal in response to said supply power changing signal; and
wherein, when said supply power changing signal is input from said power source controlling section to said cooling unit controlling section at a time of driving, said cooling unit controlling section is configured so as to calibrate cooling capability of said cooling unit.

2. The information processing unit according to claim 1, wherein said semiconductor chip comprises a CPU (Central Processing unit Unit).

3. The information processing unit according to claim 1, wherein said power source controlling section outputs one signal making up a binary signal as said signal showing a change in said amount of said supply power while said information processing unit performs an ordinary operation and outputs another signal making up said binary signal when said information processing unit is switched from its said ordinary operation to its power saving mode.

4. The information processing unit according to claim 1, wherein said semiconductor chip is mounted in a socket on a common motherboard in a manner so as to be attachable and detachable.

5. An information processing unit having at least one semiconductor chip liberating a large amount of heat and being configured so as to cool said semiconductor chip using a fan comprising:
a power source controlling section to output, when a change in supply power to be fed to said semiconductor chip occurs, a supply power change signal;
a fan controlling section to output a fan controlling signal in response to said supply power change signal; and
wherein said supply power change signal is input from said power source controlling section to said fan controlling section at a time of driving, said fan controlling section is configured so as to lower a fan revolution speed.

6. The information processing unit according to claim 5, further comprising a temperature monitoring section in which a plurality of temperature threshold values corresponding to a characteristic of each of semiconductor chips of two and more types is stored in advance, and which is selectively set to a temperature threshold value corresponding to the embedded semiconductor chip, when arbitrary one semiconductor chip out of said semiconductor chips of two or more types is embedded.

7. The information processing unit according to claim 5, wherein said semiconductor chip comprises a CPU (Central Processing unit Unit).

8. The information processing unit according to claim 5, wherein said power source controlling section outputs one signal making up a binary signal as said signal showing a change in said amount of said supply power while said information processing unit performs an ordinary operation and outputs another signal making up said binary signal when said information processing unit is switched from its said ordinary operation to its power saving mode.

9. The information processing unit according to claim 5, wherein said semiconductor chip is mounted in a socket on a common motherboard in a manner so as to be attachable and detachable.

10. The information processing unit according to claim 6, wherein said temperature monitoring section includes a BIOS (Basic Input/Output System) which stores in advance, a relative table showing a relation between said semiconductor chip and said temperature threshold value for every semiconductor chip of a different type.

11. The information processing unit according to claim 8, wherein, when one signal making up said binary signal is output as said signal showing a change in said amount of said supply power from said power source controlling section, said fan controlling section outputs a fan controlling signal to lower a fan revolution speed.

12. An information processing unit having at least one semiconductor chip liberating a large amount of heat and being configured so as to cool said semiconductor chip using a fan comprising:
a temperature monitoring section in which a plurality of temperature threshold values corresponding to a characteristic of each of semiconductor chips of two and more types is stored in advance and which is selectively set to a temperature threshold value, corresponding to the embedded semiconductor chip, when arbitrary one semiconductor chip out of said semiconductor chips of two or more types is embedded, and which outputs an alarm signal when a temperature of said semiconductor chip exceeds said temperature threshold value;
a fan controlling section to output a fan controlling signal in response to an alarm signal; and
wherein, when said alarm signal is input from said temperature monitoring section to said fan controlling section at a time of driving, said fan controlling section is configured so as to increase a fan revolution speed.

13. The information processing unit according to claim 12, wherein said semiconductor chip comprises a CPU (Central Processing unit Unit).

14. The information processing unit according to claim 12, wherein said temperature monitoring section includes a BIOS (Basic Input/Output System) which stores in advance, a relative table showing a relation between said semiconductor chip and said temperature threshold value for every semiconductor chip of a different type.

15. The information processing unit according to claim 12, wherein said semiconductor chip is mounted on a socket on a common motherboard in a manner so as to be attachable and detachable.

16. The information processing unit according to claim 14, wherein, when one signal making up said binary signal is output as said signal showing a change in said amount of said supply power from said power source controlling section, said fan controlling section outputs a fan controlling signal to lower a fan revolution speed.

17. An information processing unit having at least one semiconductor chip liberating a large amount of heat and being configured so as to cool said semiconductor chip using a fan comprising:
a power source section to feed supply power to said information processing unit;
a fan controlling section to detect a change in fed amounts of said supply power and, based on a result from the detection, to output a fan controlling signal; and
wherein, when a signal showing a change in said fed amounts of said supply power is input from said power source section to said fan controlling section at a time of driving, said fan controlling section is configured so as to lower a fan revolution speed.

18. The information processing unit according to claim 17, wherein said semiconductor chip comprises a CPU (Central Processing unit Unit).

19. The information processing unit according to claim 17, wherein said semiconductor chip is mounted on a socket on a common motherboard in a manner so as to be attachable and detachable.

20. A method for cooling an information processing unit having at least one semiconductor chip liberating a large amount of heat comprising:
a step of outputting a supply power changing signal from a power source controlling section to a cooling unit controlling section when supply power to be fed to said semiconductor chip is changed;
a step of calibrating cooling capability of a cooling unit by using said cooling unit controlling section when said supply power changing signal is input from said power source controlling section to said cooling unit controlling section at a time of driving.

21. A method for cooling an information processing unit having at least one semiconductor chip liberating a large amount of heat comprising:
a step of outputting a supply power changing signal from a power source controlling section to a fan controlling section when supply power to be fed to said semiconductor chip is changed; and
a step of lowering a fan revolution speed using said fan controlling section when said supply power changing signal is input from said power source controlling section to said fan controlling section at a time of driving.

22. A method for cooling an information processing unit having at least one semiconductor chip liberating a large amount of heat comprising:
a step of storing in advance a plurality of temperature threshold values corresponding to a characteristic of each of semiconductor chips of two or more types and, when arbitrary one semiconductor out of semiconductors of two or more types is embedded, of setting selectively said temperature threshold value to a temperature threshold value corresponding to said embedded semiconductor chip;
a step of outputting an alarm signal from a temperature monitoring section to a fan controlling section when a temperature of said semiconductor chip exceeds said temperature threshold value; and
a step of increasing a fan revolution speed using said fan controlling section when said alarm signal is input from said temperature monitoring section to said fan controlling section at a time of driving.

23. A method for cooling an information processing unit having at least one semiconductor chip liberating a large amount of heat comprising:
a step of outputting a signal showing a change in amounts of supply power from a power source section to feed supply power to said information processing unit to a fan controlling section; and
a step of lowering a fan revolution speed using said fan controlling section when said signal showing a change in said amount of said supply power is input from said power source section to said fan controlling section at a time of driving.
